(19) United States
(12) Patent Application Publication
(10) Pub. No.: US 2025/0370015 A1
(43) Pub. Date: Dec. 4, 2025

(54) POWER MONITORING DEVICE AND MONITORING METHOD THEREOF

(71) Applicant: Wistron NeWeb Corporation, Hsinchu (TW)

(72) Inventors: Chen-Shu PENG, Hsinchu (TW); Yung-Jinn CHEN, Hsinchu (TW)

(21) Appl. No.: 19/192,442

(22) Filed: Apr. 29, 2025

(30) Foreign Application Priority Data
May 30, 2024 (TW) 113120083

(51) Int. Cl. G01R 21/06; H03F 3/24

(52) U.S. Cl. CPC G01R 21/06; H03F 3/245; H03F 2200/451

(57) ABSTRACT

A power monitoring device and a monitoring method thereof are provided. The power monitoring device includes a power detection module and a processor. The power detection module converts a forward power into a forward signal, and converts a reverse power into a reverse signal. The processor is configured to determine whether the forward signal and the reverse signal meet a first judgment condition at a first time to generate a first result, and to determine whether the forward signal and the reverse signal meet a second judgment condition at a second time to generate a second result. The processor determines whether to send a warning signal based on the first result and the second result. The first time precedes the second time, and both the first judgment condition and the second judgment condition include that the forward signal is greater than the reverse signal.

### RELATED APPLICATIONS

This application claims the benefit of priority to Taiwan Patent Application No. 113120083, filed on May 30, 2024. The entire content of the above identified application is incorporated herein by reference.

### BACKGROUND

### Technical Field

The present disclosure relates to a monitoring device and a monitoring method, and more particularly, to a power monitoring device and a monitoring method thereof.

### Description of Related Art

Currently, the power amplifiers (PAs) used in Remote Radio Unit (RRU) products of Open Radio Access Network (O-RAN) are generally high-cost components.

Without real-time monitoring of the PA's health status, abnormalities in output power can go undetected, potentially leading to PA failure or burnout. Such failures can result in significant financial losses due to the high replacement cost of PAs.

Therefore, there is a clear lack of power monitoring devices and methods in the market, prompting the industry to seek effective solutions.

### SUMMARY

In one aspect, the present disclosure provides a power monitoring device, which is electrically connected to a power amplifier and an antenna. The power monitoring device includes a power detection module and a processor. The power detection module is configured to detect a forward power of the power amplifier and a reverse power of the antenna, convert the forward power into a forward signal, and convert the reverse power into a reverse signal. The processor is electrically connected to the power detection module, and is configured to determine whether the forward signal and the reverse signal meet a first judgment condition at a first time to generate a first result, and determine whether the forward signal and the reverse signal meet a second judgment condition at a second time to generate a second result. The processor determines whether to send a warning signal based on the first result and the second result. The first time precedes the second time, and both the first judgment condition and the second judgment condition include that the forward signal is greater than the reverse signal.

In another aspect, the present disclosure provides a power monitoring method that includes: detecting a forward power of a power amplifier and a reverse power of an antenna, converting the forward power into a forward signal, and converting the reverse power into a reverse signal, by a power detection module; and determining whether the forward signal and the reverse signal meet a first judgment condition at a first time to generate a first result, determining whether the forward signal and the reverse signal meet a second judgment condition at a second time to generate a second result, and determining whether to send a warning signal based on the first result and the second result, by a processor. The first time precedes the second time, and both the first judgment condition and the second judgment condition include that the forward signal is greater than the reverse signal.

### BRIEF DESCRIPTION OF THE DRAWINGS

The present disclosure can be more fully understood by reading the following detailed description of the embodiment, with reference made to the accompanying drawings as follows:

FIG. 1 is a schematic diagram of a power monitoring device according to a first embodiment of the present disclosure.

FIG. 2 is a flowchart of a power monitoring method according to a second embodiment of the present disclosure.

FIG. 3 is a flowchart of the steps of determining whether a forward signal and a reverse signal meet a first judgment condition and second judgment condition in FIG. 2.

FIG. 4 is a schematic diagram of a power monitoring device according to a third embodiment of the present disclosure.

FIG. 5 is a flowchart of a power monitoring method according to a fourth embodiment of the present disclosure.

FIG. 6 is a flowchart of the steps of determining whether the forward signal and the reverse signal meet first judgment condition, second judgment condition, the third judgment condition in FIG. 5.

### DETAILED DESCRIPTION

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of "a", "an", and "the" includes plural reference, and the meaning of "in" includes "in" and "on". Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as "first", "second" or "third" can be used to describe various components, signals or the like, which are for distinguishing one component/signal from another one only, and are not intended to, nor should be construed to impose any substantive limitations on the components, signals or the like.

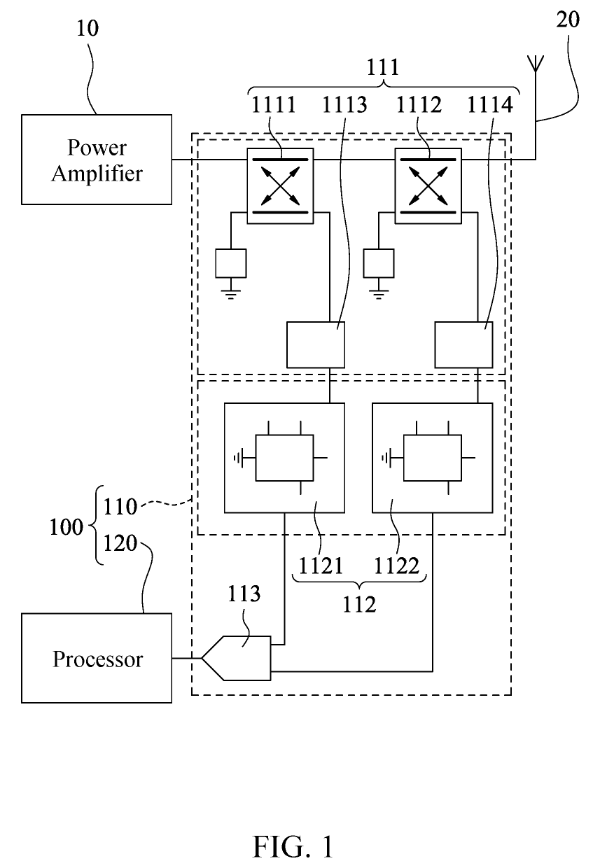

FIG. 1 is a schematic diagram of a power monitoring device 100 according to a first embodiment of the present disclosure. Referring to FIG. 1, the power monitoring device 100 is used to monitor the health status of a power amplifier 10 and, when there is an abnormality in the output power of the power amplifier 10, to immediately intervene so as to prevent damage to the power amplifier 10. The power monitoring device 100 is electrically connected to the power amplifier 10 and an antenna 20, and includes a power detection module 110 and a processor 120. The processor 120 is electrically connected to the power detection module 110. In the first embodiment, the power amplifier 10 and the antenna 20 can be amplifiers and antennas used in O-RAN remote radio unit products, but the present disclosure is not limited thereto.

The power detection module 110 is used to detect a forward power of the power amplifier 10 and a reverse power of the antenna 20. The power detection module 110 converts the forward power into a forward signal, and converts the reverse power into a reverse signal. The power detection module 110 includes a coupling circuit 111, a power detection circuit 112, and an analog-to-digital converter 113. The coupling circuit 111 is electrically connected to the power amplifier 10 and the antenna 20. The power detection circuit 112 is electrically connected to the coupling circuit 111 and the analog-to-digital converter 113. The analog-to-digital converter 113 is electrically connected to the processor 120.

The coupling circuit 111 includes a front-end coupler 1111, a back-end coupler 1112, a front-end attenuator 1113, and a back-end attenuator 1114. The front-end coupler 1111 is electrically connected to the power amplifier 10 and the front-end attenuator 1113. The back-end coupler 1112 is electrically connected to the antenna 20 and the back-end attenuator 1114. The front-end coupler 1111 is used to obtain the forward power, and the back-end coupler 1112 is used to obtain the reverse power. The front-end attenuator 1113 and the back-end attenuator 1114 are respectively used to improve the reflectivity of the front-end coupler 1111 and the back-end coupler 1112, as well as to adjust the RF power in the power detection path. This helps to prevent abnormal power readings and enhances installation flexibility.

The power detection circuit 112 includes a front-end power detector 1121 and a back-end power detector 1122. The front-end power detector 1121 is electrically connected to the front-end attenuator 1113, and the back-end power detector 1122 is electrically connected to the back-end attenuator 1114. The front-end power detector 1121 is used to convert the forward power into a forward detection signal, and the back-end power detector 1122 is used to convert the reverse power into a reverse detection signal. In the first embodiment, the front-end power detector 1121 and the back-end power detector 1122 can be radio frequency (RF) detection integrated circuits (ICs) of model LMH2110, but the present disclosure is not limited thereto.

The analog-to-digital converter 113 is used to convert the forward detection signal into a forward signal and to convert the reverse detection signal into a reverse signal. In the first embodiment, the forward signal and the reverse signal are voltage values; the analog-to-digital converter 113 can be an analog-to-digital converter integrated circuit of model TLA2024, but the present disclosure is not limited thereto.

The processor 120 is used to determine whether the forward signal and the reverse signal meet a first judgment condition at a first time to generate a first result, and to determine whether the forward signal and the reverse signal meet a second judgment condition at a second time to generate a second result. The processor 120 then determines whether to send a warning signal based on the first result and the second result. The first time precedes the second time, which means that the processor 120 first executes the judgment of the first judgment condition and then executes the judgment of the second judgment condition based on the first result. In the first embodiment, the processor 120 can be a Field Programmable Gate Array (FPGA), but the present disclosure is not limited thereto.

The first judgment condition includes a three-stage judgment formula. The first-stage judgement determines whether both the forward signal and the reverse signal are greater than a valid value. The second-stage judgement determines whether the forward signal is greater than the reverse signal. The third-stage judgement determines whether the reverse signal is greater than a threshold value, and the valid value is less than the threshold value. Specifically, the first-stage judgment formula verifies the validity of the forward signal and the reverse signal. The second-stage judgment formula serves as the core criterion for determining whether there is an abnormality in the power amplifier 10. The third-stage judgment formula validates the abnormality identified in the second stage. When the forward signal and the reverse signal fully satisfy all three stages of the first judgment condition, it indicates that the power amplifier 10 is functioning normally. In addition, the second judgment condition requires that the forward signal be greater than the reverse signal. When the forward signal and the reverse signal meet the second judgment condition, it also confirms that the power amplifier 10 is operating without abnormalities. In the first embodiment, the valid value is 100 mV, and the threshold value is 1000 mV, but the present disclosure is not limited thereto.

In other embodiments, the processor can determine whether the power amplifier is abnormal by using the difference or ratio between the forward signal and the reverse signal as the first judgment condition and the second judgment condition. Additionally, in other embodiments, the second judgment condition may also incorporate the aforementioned three-stage judgment formula to further enhance judgment accuracy.

Furthermore, in a case where there are multiple sets of power amplifiers 10 and antennas 20, the processor 120 verifies whether the forward signal and the reverse signal of each set of power amplifiers 10 and antennas 20 meet the first judgment condition at intervals within a first time period (including the first time). These intervals can be specified intervals, such as 10 ms, and can be modified according to different product requirements. And, the processor verifies whether the forward signal and the reverse signal of each set of power amplifiers 10 and antennas 20 meet the second judgment condition at intervals within a second time period (including the second time), and these intervals can also be specified intervals, such as 10 ms, and can be modified according to different product requirements.

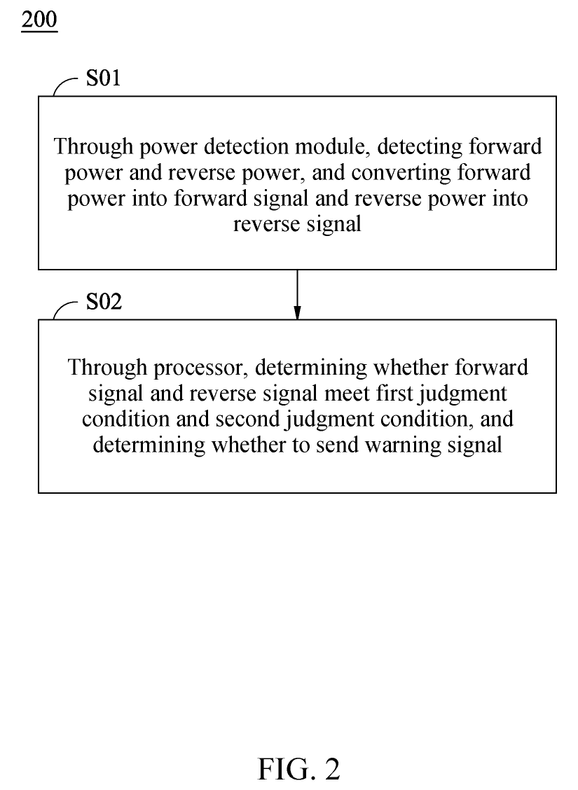

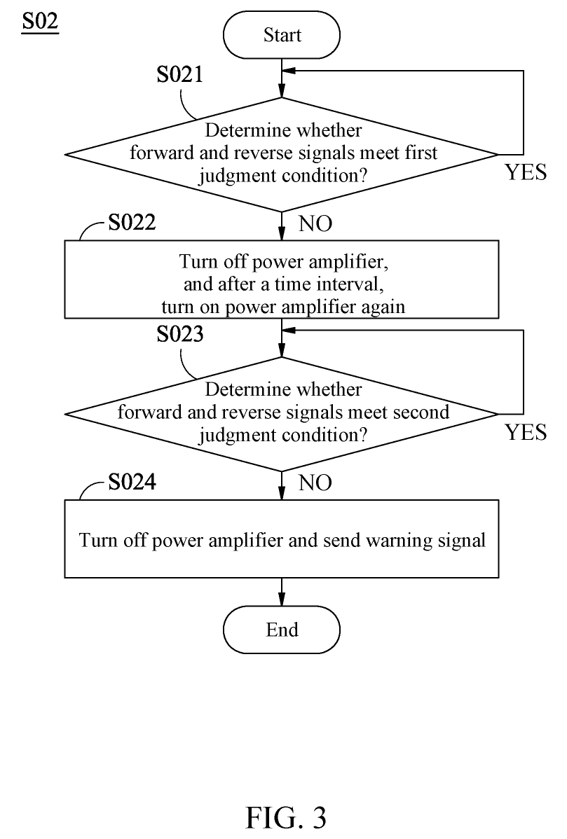

The detailed features and sequence of the processor 120 performing the judgment of the first judgment condition and the second judgment condition will be explained in conjunction with a power monitoring method 200 of FIG. 2 and FIG. 3 described herein.

FIG. 2 is a flowchart of the power monitoring method 200 according to a second embodiment of the present disclosure, and FIG. 3 is a flowchart of the steps of determining whether the forward signal and the reverse signal meet the first judgment condition and the second judgment condition in FIG. 2. Referring to FIG. 1, FIG. 2, and FIG. 3, the power monitoring device 100 is configured to implement the power monitoring method 200. It should be noted that the power monitoring method 200 of the present disclosure is not limited to being implemented by the power monitoring device 100 of the present disclosure. The elements in the power monitoring device 100 can be arbitrarily integrated into various combinations to perform the functions of the power monitoring method 200.

The power monitoring method 200 includes steps S01 and S02. In step S01, through the power detection module 110, the forward power of the power amplifier 10 and the reverse power of the antenna 20 are detected, the forward power is converted into a forward signal, and the reverse power is converted into a reverse signal. In step S02, the processor 120 determines whether the forward signal and the reverse signal meet the first judgment condition at a first time to generate a first result, determines whether the forward signal and the reverse signal meet the second judgment condition at a second time to generate a second result, and determines whether to send a warning signal based on the first result and the second result.

In FIG. 3, step S02 further includes steps S021, S022, S023, and S024. In step S021, the first result is generated based on the first judgment condition. In step S022, the power amplifier 10 is turned off and then turned on again after a time interval. In step S023, the second result is generated based on the second judgment condition. In step S024, the power amplifier 10 is turned off, and a warning signal is sent.

Specifically, in step S021, when the first result is yes, it indicates that the power amplifier 10 is functioning normally, and the processor 120 repeatedly performs step S021 to determine whether the forward signal and the reverse signal meet the first judgment condition to prevent misjudgment. When the first result is no, it indicates that the power amplifier 10 is abnormal. The processor 120 immediately executes step S022 to turn off the power amplifier 10, and after a time interval, turns on the power amplifier 10 again, and then executes step S023 to determine whether the forward signal and the reverse signal meet the second judgment condition.

In step S023, when the second result is yes, it indicates that the power amplifier 10 is functioning normally at this time, and the processor 120 repeatedly performs step S023 to determine whether the forward signal and the reverse signal meet the second judgment condition to avoid misjudgment again. When the second result is no, it indicates that the power amplifier 10 is abnormal, and the processor 120 immediately executes step S024 to turn off the power amplifier 10, and sends a warning signal. When the second result is no, because two verifications have been made, it can be inferred that the power amplifier 10 is indeed operating abnormally. In addition to turning off the power amplifier 10, the power of the remote radio unit product will also be turned off, and a warning signal will be sent to notify the engineering personnel to arrange for maintenance.

Therefore, by verifying the power of the power amplifier 10 and the antenna 20 through double verification via two judgment conditions, the power amplifier 10 can be effectively monitored to prevent damage to the power amplifier 10.

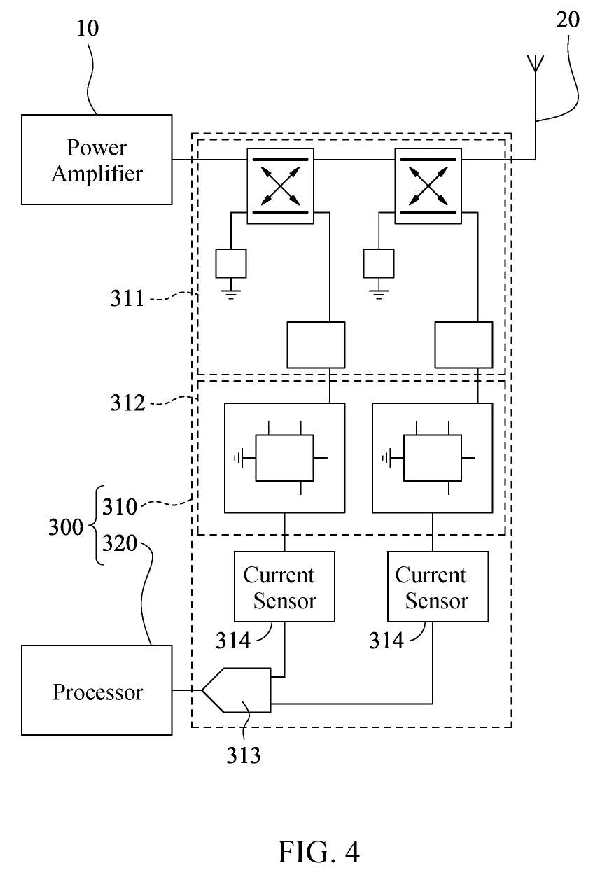

FIG. 4 is a schematic diagram of a power monitoring device 300 according to a third embodiment of the present disclosure. Referring to FIG. 4, the power monitoring device 300 includes a power detection module 310 and a processor 320. The power detection module 310 includes a coupling circuit 311, a power detection circuit 312, and an analog-to-digital converter 313. In the third embodiment, the processor 320, the coupling circuit 311, the power detection circuit 312, and the analog-to-digital converter 313 are the same as the processor 120, the coupling circuit 111, the power detection circuit 112, and the analog-to-digital converter 113 in the first embodiment, and will not be described herein. The difference between the third embodiment and the first embodiment is that the power detection module 310 further includes a current sensor 314. The current sensor 314 is electrically connected between the power detection circuit 312 and the analog-to-digital converter 313. The number of current sensors 314 is two, which are respectively used to obtain another forward signal and another reverse signal. In the third embodiment, the forward signal and the reverse signal are voltage values, and the another forward signal and the another reverse signal are current values. In other embodiments, the forward signal and the reverse signal can be current values, and the another forward signal and the another reverse signal can be voltage values. The current values can be obtained through the current sensor or by converting the forward power and the reverse power. The present disclosure is not limited thereto.

The processor 320 is also used to determine whether the another forward signal and the another reverse signal meet a third judgment condition at a third time to generate a third result. The processor 320 determines whether to send a warning signal based on the first result, the second result, and the third result. The second time precedes the third time, in other words, the processor 320 first executes the judgment of the second judgment condition and then executes the judgment of the third judgment condition based on the second result.

The third judgment condition includes that the another forward signal is greater than the another reverse signal. When the another forward signal and the another reverse signal meet the third judgment condition, it can further ensure that the power amplifier 10 is not abnormal. In other embodiments, the processor can determine whether the power amplifier is abnormal by using the difference or ratio between the another forward signal and the another reverse signal as the third judgment condition. Additionally, in other embodiments, the third judgment condition may also incorporate the aforementioned three-stage judgment formula to enhance judgment accuracy.

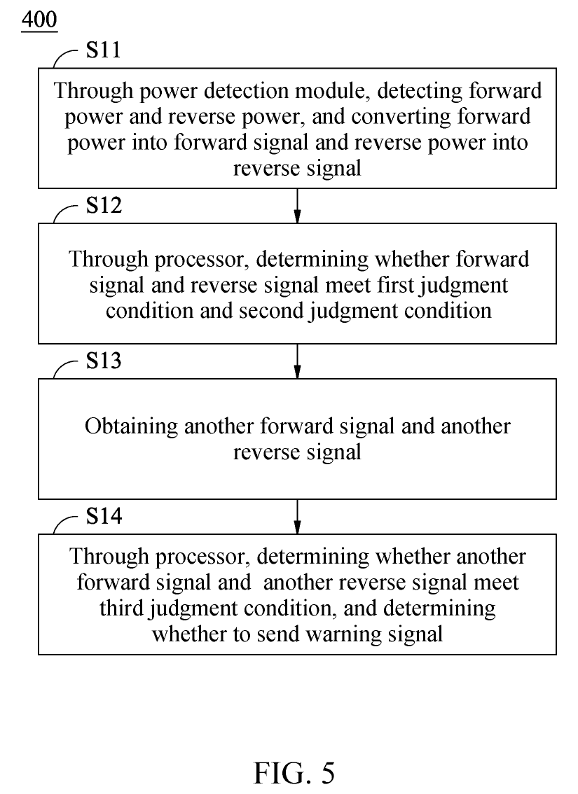

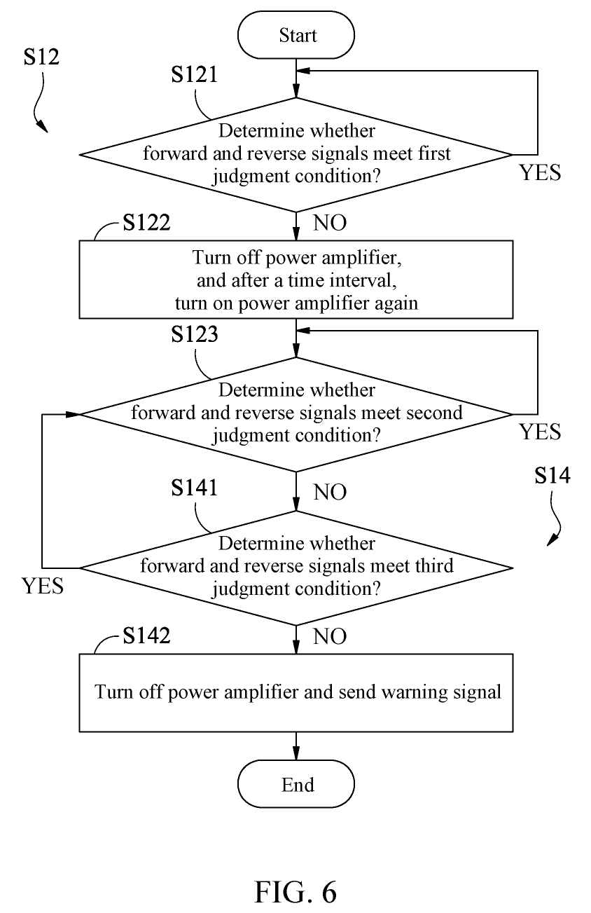

The detailed features and sequence of the processor 320 performing the judgment of the first judgment condition, the second judgment condition, and the third judgment condition will be explained in conjunction with a power monitoring method 400 of FIG. 5 and FIG. 6 described herein.

FIG. 5 is a flowchart of the power monitoring method 400 according to a fourth embodiment of the present disclosure, and FIG. 6 is a flowchart of the steps of determining whether the forward signal and the reverse signal meet the first judgment condition, the second judgment condition, and the third judgment condition in FIG. 5. Referring to FIG. 5 and FIG. 6, the power monitoring device 300 is configured to implement the power monitoring method 400. It should be noted that the power monitoring method 400 of the present disclosure is not limited to being implemented by the power monitoring device 300 of the present disclosure. The elements in the power monitoring device 300 can be arbitrarily integrated into various combinations to perform the functions of the power monitoring method 400.

In the fourth embodiment, the power monitoring method 400 includes steps S11, S12, S13, and S14. Step S11 is the same as step S01 of the second embodiment and will not be described herein. In step S12, the processor 320 determines whether the forward signal and the reverse signal meet the first judgment condition at a first time to generate a first result, and determines whether the forward signal and the reverse signal meet the second judgment condition at a second time to generate a second result. In step S13, another forward signal and another reverse signal are obtained by the current sensor 314 of the power detection module 310. In step S14, the processor 320 determines whether the another forward signal and the another reverse signal meet the third judgment condition at a third time to generate a third result, and the processor 320 determines whether to send a warning signal based on the first result, the second result, and the third result.

In FIG. 6, step S12 further includes steps S121, S122, and S123, and step S14 further includes steps S141 and S142. In step S121, the first result is generated based on the first judgment condition. In step S122, the power amplifier 10 is turned off and then turned on again after a time interval. In step S123, the second result is generated based on the second judgment condition. In step S141, the third result is generated based on the third judgment condition. In step S142, the power amplifier 10 is turned off, and a warning signal is sent.

Specifically, in step S121, when the first result is yes, it indicates that the power amplifier 10 is functioning normally, and the processor 320 repeatedly performs step S121 to determine whether the subsequently obtained forward signal and reverse signal meet the first judgment condition to avoid misjudgment. When the first result is no, it indicates that there is abnormality in the power amplifier 10, and the processor 320 immediately executes step S122 to turn off the power amplifier 10, and after a time interval, turns on the power amplifier 10 again. Then the processor 320 performs step S123 to determine whether the currently obtained forward signal and reverse signal meet the second judgment condition.

In step S123, when the second result is yes, it indicates that the power amplifier 10 is functioning normally at this time, and the processor 320 then repeatedly performs step S123 to determine whether the subsequently obtained forward signals and reverse signals meet the second judgment condition to prevent further misjudgment. When the second result is no, it indicates that the power amplifier 10 has been confirmed as abnormal twice, and the processor 320 immediately executes step S141 to determine whether the another forward signal and the another reverse signal meet the third judgment condition, using current value signals, which differs from voltage values, for a third verification.

In step S141, when the third result is yes, the processor 320 repeatedly performs step S123 to determine whether the subsequently obtained forward signals and reverse signals meet the second judgment condition to further avoid misjudgment again. When the third result is no, it indicates that the power amplifier 10 is abnormal, and the processor 320 immediately executes step S142 to turn off the power amplifier 10 and send a warning signal. When the third result is no, because three verifications with different parameter signals (voltage and current signals) have been made, it can be inferred that the power amplifier 10 is indeed abnormal. In addition to turning off the power amplifier 10, the power of the remote radio unit product will also be turned off, and a warning signal will be sent to notify the engineering personnel to arrange for maintenance. However, the present disclosure is not limited thereto.

From the above embodiments, the present disclosure has the following advantages. First, by verifying the power of the power amplifier and the antenna through multiple validation steps based on various judgment conditions, the health status of the power amplifier can be effectively monitored. This enables immediate intervention when an abnormal output power is detected, preventing damage to the power amplifier and thereby effectively achieving the purpose of cost optimization. Second, by utilizing dual confirmation with different parameter signals (voltage and current signals), the accuracy of the assessment is enhanced, reducing the risk of the processor making an incorrect judgment and unnecessarily shutting down the power amplifier.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A power monitoring device, electrically connected to a power amplifier and an antenna, the power monitoring device comprising:
a power detection module, configured to detect a forward power of the power amplifier and a reverse power of the antenna, convert the forward power into a forward signal, and convert the reverse power into a reverse signal; and
a processor, electrically connected to the power detection module, and configured to determine whether the forward signal and the reverse signal meet a first judgment condition at a first time to generate a first result, determine whether the forward signal and the reverse signal meet a second judgment condition at a second time to generate a second result, and determine whether to send a warning signal based on the first result and the second result;
wherein the first time precedes the second time, and both the first judgment condition and the second judgment condition include that the forward signal is greater than the reverse signal.

2. The power monitoring device of claim 1, wherein,
when the first result is yes, the processor repeatedly determines whether the forward signal and the reverse signal meet the first judgment condition;
when the first result is no, the processor turns off the power amplifier, turns it on again after a time interval, and determines whether the forward signal and the reverse signal meet the second judgment condition; and
when the second result is yes, the processor repeatedly determines whether the forward signal and the reverse signal meet the second judgment condition.

3. The power monitoring device of claim 2, wherein,
when the second result is no, the processor turns off the power amplifier and sends the warning signal.

4. The power monitoring device of claim 2, wherein the power detection module is further configured to obtain another forward signal and another reverse signal, the processor is further configured to determine whether the another forward signal and the another reverse signal meet a third judgment condition at a third time to generate a third result, and the processor determines whether to send the warning signal based on the first result, the second result, and the third result;
wherein the second time precedes the third time, and the third judgment condition includes that the another forward signal is greater than the another reverse signal.

5. The power monitoring device of claim 4, wherein,
when the second result is no, the processor determines whether the another forward signal and the another reverse signal meet the third judgment condition; when the third result is yes, the processor repeatedly determines whether the forward signal and the reverse signal meet the second judgment condition;
and when the third result is no, the processor turns off the power amplifier and sends the warning signal.

6. The power monitoring device of claim 4, wherein each of the forward signal and the reverse signal is a voltage value, and each of the another forward signal and the another reverse signal is a current value.

7. The power monitoring device of claim 1, wherein the first judgment condition further includes that the forward signal is greater than a valid value, and the reverse signal is greater than the valid value.

8. The power monitoring device of claim 7, wherein the first judgment condition further includes that the reverse signal is greater than a threshold value, and the valid value is less than the threshold value.

9. The power monitoring device of claim 1, wherein the power detection module comprises:
a coupling circuit, electrically connected to the power amplifier and the antenna, and configured to obtain the forward power and the reverse power;
a power detection circuit, electrically connected to the coupling circuit, and configured to convert the forward power into a forward detection signal, and convert the reverse power into a reverse detection signal; and an analog-to-digital converter, electrically connected to the power detection circuit and the processor, and configured to convert the forward detection signal into the forward signal, and convert the reverse detection signal into the reverse signal.

10. The power monitoring device of claim 9, wherein the power detection module further comprises a current sensor electrically connected between the power detection circuit and the analog-to-digital converter.

11. A power monitoring method comprising:
detecting a forward power of a power amplifier and a reverse power of an antenna, converting the forward power into a forward signal, and converting the reverse power into a reverse signal, by a power detection module;
determining whether the forward signal and the reverse signal meet a first judgment condition at a first time to generate a first result, determining whether the forward signal and the reverse signal meet a second judgment condition at a second time to generate a second result, and determining whether to send a warning signal based on the first result and the second result, by a processor;
wherein the first time precedes the second time, and both the first judgment condition and the second judgment condition include that the forward signal is greater than the reverse signal.

12. The power monitoring method of claim 11, wherein,
when the first result is yes, the processor repeatedly determines whether the forward signal and the reverse signal meet the first judgment condition; when the first result is no, the processor turns off the power amplifier, turns it on again after a time interval, and determines whether the forward signal and the reverse signal meet the second judgment condition; and
when the second result is yes, the processor repeatedly determines whether the forward signal and the reverse signal meet the second judgment condition.

13. The power monitoring method of claim 12, wherein,
when the second result is no the processor turns off the power amplifier and sends the warning signal.

14. The power monitoring method of claim 12, further comprising:
obtaining another forward signal and another reverse signal by the power detection module; and
determining whether the another forward signal and the another reverse signal meet a third judgment condition at a third time to generate a third result, and determining whether to send the warning signal based on the first result, the second result, and the third result, by the processor;
wherein the second time precedes the third time, and the third judgment condition includes that the another forward signal is greater than the another reverse signal.

15. The power monitoring method of claim 14, wherein, when the second result is no, the processor determines whether the another forward signal and the another reverse signal meet the third judgment condition;
when the third result is yes, the processor repeatedly determines whether the forward signal and the reverse signal meet the second judgment condition;
and when the third result is no, the processor turns off the power amplifier and sends the warning signal.

16. The power monitoring method of claim 14, wherein each of the forward signal and the reverse signal is a voltage value, and each of the another forward signal and the another reverse signal is a current value.

17. The power monitoring method of claim 11, wherein the first judgment condition further includes that the forward signal is greater than a valid value, and the reverse signal is greater than the valid value.

18. The power monitoring method of claim 17, wherein the first judgment condition further includes that the reverse signal is greater than a threshold value,
and the valid value is less than the threshold value.
